(19) United States
(12) Patent Application Publication
(10) Pub. No.: US 2026/0130221 A1
(43) Pub. Date: May 7, 2026

(54) SEMICONDUCTOR PACKAGE

(71) Applicant: Samsung Electronics Co., Ltd., Suwon-si (KR)

(72) Inventors: Hyeonmin Lee, Suwon-si (KR); Hyungchul Shin, Suwon-si (KR)

(21) Appl. No.: 19/377,240

(22) Filed: Nov. 3, 2025

(30) Foreign Application Priority Data
Nov. 5, 2024 (KR) 10-2024-0155691

(51) Int. Cl. H01L 23/00; H01L 23/31; H01L 25/065; H01L 23/48

(52) U.S. Cl. CPC H10W 42/00; H10W 74/117; H10W 90/00; H10W 20/20; H10W 90/724; H10W 90/792

(57) ABSTRACT

A semiconductor package is provided. The semiconductor package includes a base chip, a plurality of first semiconductor chips stacked on the base chip, a dummy chip stacked on an uppermost first semiconductor chip of the plurality of first semiconductor chips, and a molding structure surrounding the base chip, the plurality of first semiconductor chips, and the dummy chip, wherein the dummy chip includes a channel extending from an upper surface of the dummy chip to a lower surface of the dummy chip, the channel has a shape extending from a center of the dummy chip to at least any one point located at an edge of the dummy chip, in a horizontal direction in a top view, and the molding structure fills the channel.

### CROSS-REFERENCE TO RELATED APPLICATIONS

This application is based on and claims priority under 35 U.S.C. §119 to Korean Patent Application No. 10-2024-0155691, filed on November 5, 2024, in the Korean Intellectual Property Office, the disclosure of which is incorporated by reference herein in its entirety.

### BACKGROUND

Recently, the demand for portable devices has rapidly increased in the electronics product market, and accordingly, miniaturization and lightening of electronic components mounted in electronic products have been continuously demanded. For miniaturization and lightening of electronic components, semiconductor packages mounted in the electronic components have been demanded to process high-capacity data with a small volume and reduced defects.

In addition, a semiconductor package can have a plurality of semiconductor chips stacked in the vertical direction to reduce the size of the semiconductor package. However, when a plurality of semiconductor chips are hybrid-bonded, the structural reliability of a semiconductor package may decrease.

### SUMMARY

The present disclosure provides a semiconductor package with improved reliability.

In addition, the problems to be solved by the technical idea of the present disclosure are not limited to the problem mentioned above, and other problems could be clearly understood by those of ordinary skill in the art from the description below.

To solve the technical problems of the present disclosure, the following semiconductor packages are provided.

According to an aspect of the present disclosure, a semiconductor package includes a base chip, a plurality of first semiconductor chips stacked on the base chip, a dummy chip stacked on an uppermost first semiconductor chip among the plurality of first semiconductor chips, and a molding member surrounding the base chip, the plurality of first semiconductor chips, and the dummy chip, wherein the dummy chip includes a channel extending from an upper surface of the dummy chip to a lower surface of the dummy chip, the channel has a shape extending from a center of the dummy chip to at least any one point located at an edge of the dummy chip, in a horizontal direction in a top view, and the molding member fills the channel.

According to another aspect of the present disclosure, a semiconductor package includes a base chip, a plurality of first semiconductor chips stacked on the base chip, and a dummy chip stacked on an uppermost first semiconductor chip among the plurality of first semiconductor chips and having a channel extending upward from a lower surface of the dummy chip, wherein the channel extends from a center of the dummy chip to at least four points located at an edge of the dummy chip, in a top view, the plurality of first semiconductor chips are stacked through direct bonding, and the dummy chip is not electrically connected to the plurality of first semiconductor chips.

According to another aspect of the present disclosure, a semiconductor package includes a first substrate, a base chip disposed on the first substrate, a plurality of first semiconductor chips stacked on the base chip, a dummy chip stacked on an uppermost first semiconductor chip among the plurality of first semiconductor chips and having a channel extending from a lower surface of the dummy chip to an upper surface of the dummy chip, a first molding member surrounding the base chip, the plurality of first semiconductor chips, and the dummy chip and filling the channel, and a second molding member surrounding respective side surfaces of the first molding member and the base chip on the first substrate, wherein a semiconductor chip pad and a dielectric layer surrounding a side surface of the semiconductor chip pad are provided on each of lower surfaces and upper surfaces of the plurality of first semiconductor chips, the channel has a shape extending from a center of the dummy chip to at least any four points located at an edge of the dummy chip, in a horizontal direction in a top view, and an upper surface of the first molding member is coplanar with the upper surface of the dummy chip.

### BRIEF DESCRIPTION OF THE DRAWINGS

Embodiments of the present disclosure will be more clearly understood from the following detailed description taken in conjunction with the accompanying drawings.

FIG. 1 is a top view schematically illustrating a semiconductor package according to implementations.

FIG. 2 is a cross-sectional view taken along line X1-X1' of the semiconductor package of FIG. 1.

FIG. 3 is a top view schematically illustrating a semiconductor package according to implementations.

FIG. 4 is a cross-sectional view taken along line X1-X1' of the semiconductor package of FIG. 3.

FIG. 5 is a top view schematically illustrating a semiconductor package according to implementations.

FIG. 6 is a cross-sectional view taken along line X1-X1' of the semiconductor package of FIG. 5.

FIG. 7 is a top view schematically illustrating a semiconductor package according to implementations.

FIG. 8 is a cross-sectional view taken along line X1-X1' of the semiconductor package of FIG. 7.

FIGS. 9 to 12B are cross-sectional views for describing methods of manufacturing semiconductor packages, according to implementations.

FIG. 13 is a cross-sectional view schematically illustrating a semiconductor package according to implementations.

FIG. 14 is a cross-sectional view schematically illustrating a semiconductor package according to implementations.

FIG. 15 is a cross-sectional view schematically illustrating a semiconductor package according to implementations.

### DETAILED DESCRIPTION

Hereinafter, implementations are described in detail with reference to the accompanying drawings. Like reference numerals in the drawings denote like elements, and thus their repetitive description will be omitted.

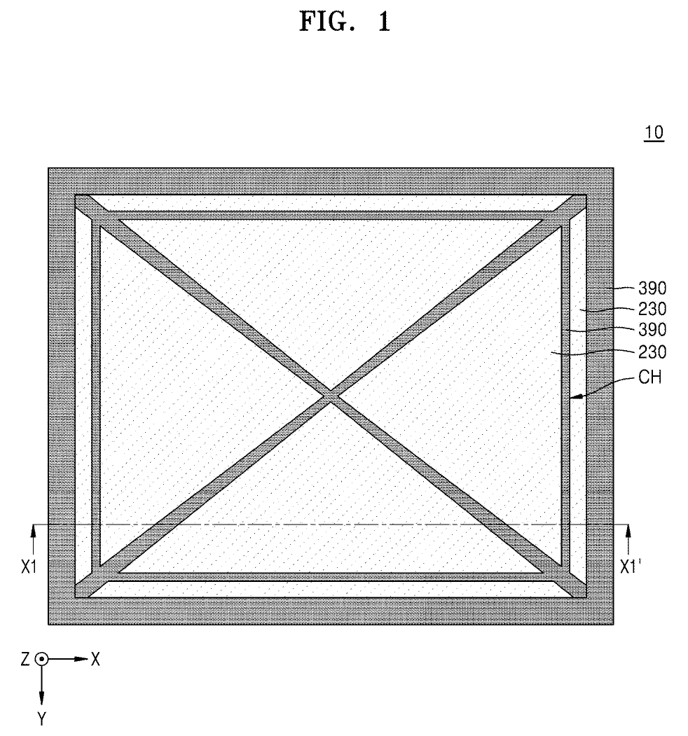

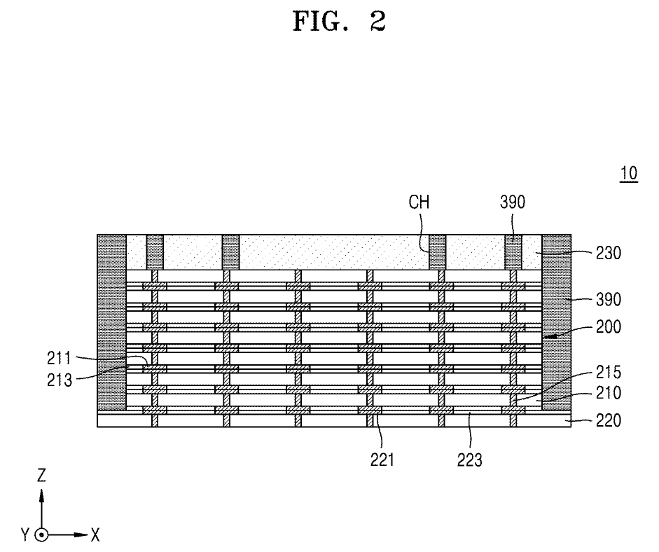

FIG. 1 is a top view schematically illustrating a semiconductor package 10 according to implementations. FIG. 2 is a cross-sectional view taken along line X1-X1' of the semiconductor package 10 of FIG. 1.

Referring to FIGS. 1 and 2, the semiconductor package 10 may include a chip-stacked structure 200 and a first molding member 390. The molding member can also be referred to as a molding structure in the present disclosure.

The chip-stacked structure 200 may include a base chip 220, a first semiconductor chip 210, and a dummy chip 230. The base chip 220 may be the lowermost chip in the chip-stacked structure 200. According to implementations, the base chip 220 may integrate signals of a plurality of first semiconductor chips 210 stacked on the base chip 220 and transmit the same to the outside, or transmit a signal and power from the outside to the plurality of first semiconductor chips 210. Accordingly, the base chip 220 may be referred to as a buffer chip or a control chip in the specification. According to implementations, the base chip 220 may have a footprint larger than that of the first semiconductor chip 210, as shown in FIG. 2, but is not limited thereto, and the base chip 220 may have a footprint substantially the same as that of the first semiconductor chip 210. That is, the base chip 220 may have a size larger than or substantially the same as that of the first semiconductor chip 210.

The base chip 220 may include various types of individual devices. The individual devices may include various microelectronics devices, e.g., a metal-oxide-semiconductor field effect transistor (MOSFET), such as a complementary metal-oxide-semiconductor (CMOS) transistor, a system large scale integration (LSI) chip, an image sensor, such as a CMOS imaging sensor (CIS), a micro-electro-mechanical system (MEMS), an active device, a passive device, and the like. In some implementations, the base chip 220 may not include a memory cell. For example, a semiconductor device included in the base chip 220 may include a serial-parallel conversion circuit, a test logic circuit, such as a design for test (DFT) circuit, a joint test action group (JTAG) circuit, or a memory built-in self-test (MBIST) circuit, and a signal interface circuit, such as a physical layer (PHY) circuit.

The first semiconductor chip 210 may be stacked on the base chip 220 in a vertical direction Z. The first semiconductor chip 210 may be bonded onto the base chip 220 through direct bonding. The direct bonding may include dielectric-to-dielectric bonding, copper (Cu)-to-Cu bonding, and hybrid bonding that is a combination of dielectric-to-dielectric bonding and metal-to-metal bonding. The direct bonding may be diffusion bonding of arranging two interfaces including the same material to face each other, then bringing the two interfaces into contact with each other, and applying heat to the same such that the two interfaces are integrated through diffusion of metal atoms or dielectric materials coming into contact with each other. The hybrid bonding may include hybrid copper bonding (HCB). Particularly, a semiconductor chip pad 211 and a dielectric layer 213 on the lower surface of the lowermost first semiconductor chip 210 may be directly bonded onto a base chip pad 221 and a dielectric layer 223 on the upper surface of the base chip 220, respectively. According to implementations, a plurality of first semiconductor chips 210 may be provided. The plurality of first semiconductor chips 210 may be defined as chips stacked on the base chip 220 in the vertical direction Z and located under the dummy chip 230 among a plurality of chips included in the chip-stacked structure 200. According to implementations, a total of seven first semiconductor chips 210 may be provided. However, the number of first semiconductor chips 210 is not limited thereto and may be one or more. The first semiconductor chip 210 may be referred to as a memory chip or a core chip.

According to implementations, the first semiconductor chip 210 may include the semiconductor chip pad 211, the dielectric layer 213, and a first through electrode 215. The semiconductor chip pad 211 may be provided on each of the upper surface and the lower surface of the first semiconductor chip 210. The dielectric layer 213 may surround the semiconductor chip pad 211 on each of the upper surface and the lower surface of the first semiconductor chip 210. In this case, the dielectric layer 213 may surround the side surface of the semiconductor chip pad 211, and any one of the upper surface and the lower surface of the semiconductor chip pad 211 may be exposed from the dielectric layer 213 in the vertical direction Z.

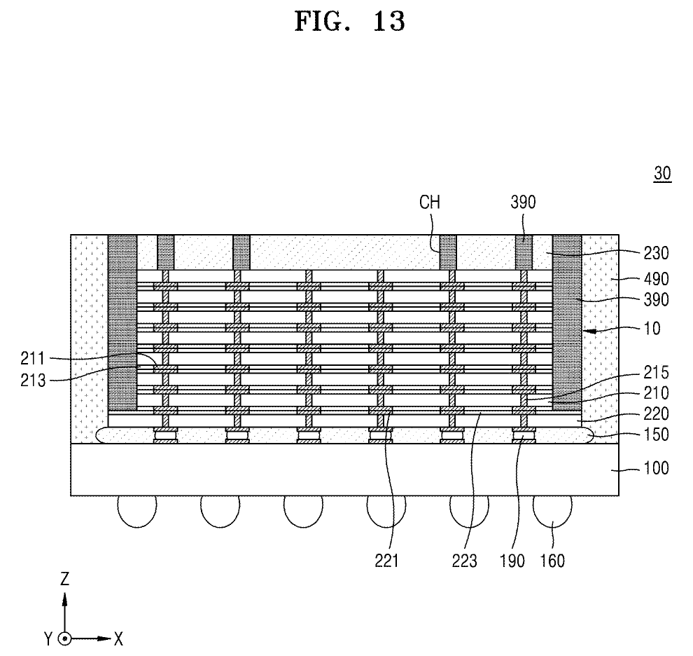

The first semiconductor chip 210 may include a first semiconductor substrate. The first semiconductor substrate may have a lower surface and an upper surface opposite to each other. The lower surface of the first semiconductor substrate may be a surface facing a first substrate 100 (see FIG. 13). The lower surface of the first semiconductor substrate may be referred to as an active surface, and the upper surface opposite to the lower surface of the first semiconductor substrate may be referred to as an inactive surface.

The first semiconductor substrate may include silicon (Si), e.g., monocrystalline Si. polycrystalline Si, or amorphous Si. Alternatively, the first semiconductor substrate may include a semiconductor element, such as germanium (Ge), or a compound semiconductor, such as silicon carbide (SiC), gallium arsenide (GaAs), indium arsenide (InAs), or indium phosphide (InP). In addition, the first semiconductor substrate may have a silicon on insulator (SOI) structure. For example, the first semiconductor substrate may include a buried oxide (BOX) layer. The first semiconductor substrate may include a conductive area, e.g., an impurity-doped well or an impurity-doped structure. In addition, the first semiconductor substrate may have various device isolation structures, such as a shallow trench isolation (STI) structure.

The first semiconductor chip 210 may include a first semiconductor device layer. According to implementations, the first semiconductor device layer may be formed on the lower surface of the first semiconductor substrate, which is the active surface of the first semiconductor substrate. The first semiconductor device layer may include a core area and a first dummy area. Individual devices may be formed in the core area of the first semiconductor device layer. The individual devices may include various microelectronics devices, e.g., a MOSFET, such as a CMOS transistor, a system LSI chip, an image sensor, such as a CIS, an MEMS, an active device, a passive device, and the like.

The first through electrode 215 may be formed to pass through the first semiconductor substrate of the first semiconductor chip 210 in the vertical direction Z. In some implementations, the first through electrode 215 may be formed to pass through a portion of the first semiconductor device layer and the first semiconductor substrate. The first through electrode 215 may be electrically connected to wirings provided inside the first semiconductor device layer. The first through electrode 215 may have a tapered shape of which the horizontal width gradually decreases or increases as the vertical level of the first through electrode 215 increases. At least a portion of the first through electrode 215 may have a pillar shape. The first through electrode 215 may be a through silicon via (TSV).

The plurality of first semiconductor chips 210 may be stacked in a line in the vertical direction Z. For example, the respective side surfaces of the plurality of first semiconductor chips 210 may be coplanar with each other. However, the plurality of first semiconductor chips 210 are not limited thereto and may be stacked offset in one direction.

In some implementations, the plurality of first semiconductor chips 210 may be stacked in the vertical direction Z through direct bonding. The direct bonding may include dielectric-to-dielectric bonding, Cu-to-Cu bonding, and hybrid bonding that is a combination of dielectric-to-dielectric bonding and metal-to-metal bonding. The direct bonding may be diffusion bonding of arranging two interfaces including the same material to face each other, then bringing the two interfaces into contact with each other, and applying heat to the same such that the two interfaces are integrated through diffusion of metal atoms or dielectric materials coming into contact with each other. The hybrid bonding may include HCB.

Because the plurality of first semiconductor chips 210 are stacked through direct bonding, dielectric layers 213 facing each other and semiconductor chip pads facing each other may be located on the interface of first semiconductor chips 210 adjacent to each other in the vertical direction Z. In addition, an adhesive layer and a bump may not be provided between the plurality of first semiconductor chips 210.

According to implementations, the length of the first semiconductor chip 210 in a first horizontal direction X may be less than the length of the base chip 220 in the first horizontal direction X. The footprint of the first semiconductor chip 210 may be less than the footprint of the base chip 220. However, the length and the footprint of the first semiconductor chip 210 are not limited thereto, and the length of the first semiconductor chip 210 in the first horizontal direction X may be substantially the same as the length of the base chip 220 in the first horizontal direction X. In addition, the footprint of the first semiconductor chip 210 may be substantially the same as the footprint of the base chip 220.

According to implementations, the first semiconductor chip 210 may include a memory chip. The memory chip may be, for example, a volatile memory chip, such as dynamic random access memory (DRAM) or static random access memory (SRAM), or a non-volatile memory chip, such as phase-change random access memory (PRAM), magnetoresistive random access memory (MRAM), ferroelectric random access memory (FeRAM), or resistive random access memory (RRAM). In addition, according to implementations, the memory chip may be a high bandwidth memory (HBM) package or a wire-bonding memory package, in which a plurality of memory chips are stacked in the vertical direction Z. However, the first semiconductor chip 210 is not limited thereto and may include a logic chip, such as a microprocessor, such as a central processing unit (CPU), a graphics processing unit (GPU), or an application processor (AP), an analog device, or a digital signal processor.

The dummy chip 230 may be stacked on the uppermost first semiconductor chip 210 in the vertical direction Z. According to implementations, the dummy chip 230 may include a channel CH.

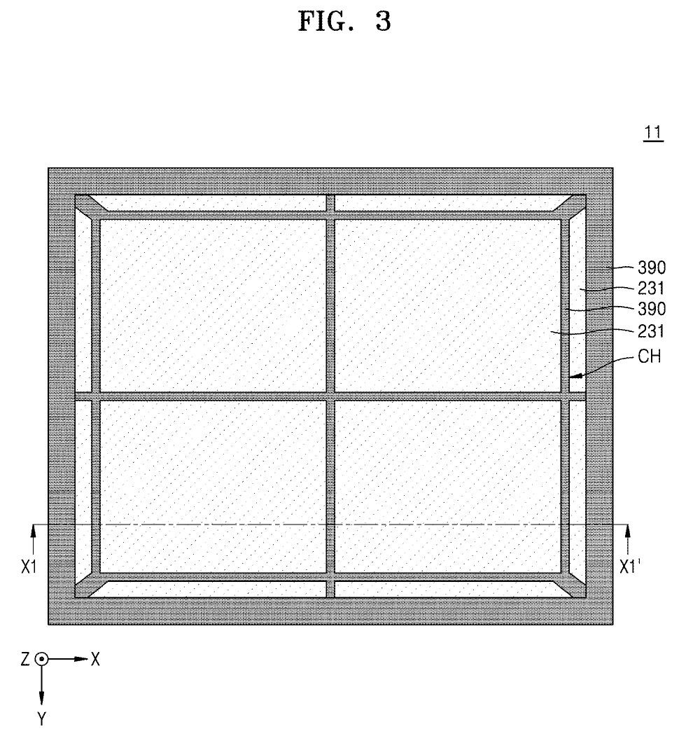

The channel CH may have a shape extending in a horizontal direction X and/or Y by passing through the dummy chip 230 from the upper surface to the lower surface of the dummy chip 230 in the vertical direction Z. According to implementations, when the dummy chip 230 is viewed from the top in the vertical direction Z, the channel CH may have a shape extending from the center of the dummy chip 230 to at least one point of an edge of the dummy chip 230 in the horizontal direction X and/or Y. For example, the channel CH of the dummy chip 230 may have a shape extending from the center of the dummy chip 230 to each of the four vertices of the dummy chip 230 when viewing the channel CH from the top in the vertical direction Z. Accordingly, the channel CH may have an X shape when viewing the channel CH from the top in the vertical direction Z. Alternatively, in some implementations, the channel CH may have a shape obtained by adding a rectangular ring to the X shape. The rectangular ring shape may be a shape with a rectangular outer boundary and a hollow center, as shown in FIG. 3. The hollow center can also have a rectangular shape. The rectangular ring also can be referred to as a rectangular frame. For example, the channel CH may further include a rectangular ring shape smaller than the dummy chip 230. The rectangular ring-shaped channel CH may be formed in the edge of the dummy chip 230. Accordingly, the channel CH may have a shape obtained by adding a rectangular ring shape to an X shape connecting from the center of the dummy chip 230 to the four vertices of the dummy chip 230. Herein, the rectangular ring shape may partially overlap the X shape. In other words, the channel CH may have a first portion having an X shape and a second potion having a rectangular ring shape, and the first portion may partially overlap the second portion.

However, the shape of the channel CH is not limited thereto, and the channel CH may have any shape capable of acting as a passage connecting from the center of the dummy chip 230 to at least any one point in the edge of the dummy chip 230.

According to implementations, the volume of the channel CH in the dummy chip 230 may be within a range of about 1 % to about 3 % of the volume of the dummy chip 230. When the volume of the channel CH in the dummy chip 230 is within the range of about 1 % to about 3 % of the volume of the dummy chip 230, bonding between the dummy chip 230 and the uppermost first semiconductor chip 210 may be smoothly performed, and the occurrence of voids between the dummy chip 230 and the uppermost first semiconductor chip 210 may also be suppressed.

According to implementations, the thickness of the dummy chip 230 in the vertical direction Z may be greater than the thickness of the first semiconductor chip 210 in the vertical direction Z. In some implementations, the cross-section of the channel CH on an X-Z plane may have a rectangular shape. For example, the cross-section of the channel CH on the X-Z plane may have a rectangular shape passing from the lower surface of the dummy chip 230 to the upper surface of the dummy chip 230. That is, the side surface of the cross-section of the channel CH on the X-Z plane may form 90 degrees with respect to the lower surface of the dummy chip 230.

The dummy chip 230 may be stacked on the upper surface of the uppermost first semiconductor chip 210 through direct bonding. Accordingly, a dielectric layer and a dummy chip pad may be formed on the lower surface of the dummy chip 230. In this case, the dielectric layer may include a material substantially the same as that of the dielectric layer 213 of the first semiconductor chip 210, and the dummy chip pad may include a material substantially the same as that of the semiconductor chip pad 211 of the first semiconductor chip 210.

The first molding member 390 may be formed on the upper surface of the base chip 220 to surround the chip-stacked structure 200. For example, the first molding member 390 may surround the side surfaces of the plurality of first semiconductor chips 210 and the dummy chip 230 on the upper surface of the base chip 220. The first molding member 390 may be formed of a molding material, such as an epoxy mold compound (EMC), or a photosensitive material, such as a photoimageable encapsulant (PIE). In some implementations, a portion of the first molding member 390 may be formed of an insulating material, such as a silicon oxide film, a silicon nitride film, or a silicon oxynitride film. However, the first molding member 390 is not limited thereto and may be formed of a thermosetting resin, such as an epoxy resin, a thermoplastic resin, such as polyimide, or a resin including a reinforcing material, such as an inorganic filler, in addition thereto, particularly, an Ajinomoto build-up film (ABF), flame retardant class 4 (FR-4), bismaleimide triazine (BT), or the like.

According to implementations, the upper surface of the first molding member 390 may be coplanar with the upper surface of the dummy chip 230. That is, the vertical level of the upper surface of the first molding member 390 may be substantially the same as the vertical level of the upper surface of the dummy chip 230.

The first molding member 390 may fully fill the channel CH of the dummy chip 230. The shape of the first molding member 390 located inside the channel CH of the dummy chip 230 may be substantially the same as the shape of the channel CH. For example, the first molding member 390 located inside the channel CH of the dummy chip 230 may have a shape extending from the center of the dummy chip 230 to at least one point of the edge of the dummy chip 230 when viewing the first molding member 390 from the top in the vertical direction Z. In addition, the cross-section of the first molding member 390 located inside the channel CH of the dummy chip 230, on the X-Z plane, may have a rectangular shape.

The upper surface of the first molding member 390 located inside the channel CH of the dummy chip 230 may be exposed upward from the dummy chip 230 in the vertical direction Z. That is, the upper surface of the first molding member 390 located inside the channel CH of the dummy chip 230 may be coplanar with the upper surface of the dummy chip 230. Because the upper surface of the first molding member 390 located inside the channel CH of the dummy chip 230 is exposed upward in the vertical direction Z, it may be easily observed whether the channel CH of the dummy chip 230 is fully filled with the first molding member 390.

In some situations, when the dummy chip 230 is bonded onto the uppermost first semiconductor chip 210 of the chip-stacked structure 200, voids may occur between the uppermost first semiconductor chip 210 and the dummy chip 230. In particular, when the plurality of first semiconductor chips 210 are stacked through direct bonding, there may occur a case where a step difference occurs between first semiconductor chips 210 because an adhesive layer is not provided between the first semiconductor chips 210, and accordingly, an area in which voids occur between the dummy chip 230 and the uppermost first semiconductor chip 210 may increase.

However, in the semiconductor package 10 according to implementations of the present disclosure, the channel CH formed inside the dummy chip 230 located on the top of the chip-stacked structure 200 may act as a passage connecting from the center of the dummy chip 230 to the outer periphery of the dummy chip 230. By doing this, when the dummy chip 230 is bonded onto the uppermost first semiconductor chip 210, even if voids occur between the dummy chip 230 and the uppermost first semiconductor chip 210, gas remaining in the voids may be discharged to the outside of the dummy chip 230 through the channel CH, and thus, bonding between the dummy chip 230 and the uppermost first semiconductor chip 210 may be performed without voids.

In addition, after bonding between the dummy chip 230 and the uppermost first semiconductor chip 210 is completed, the first molding member 390 fills the channel CH of the dummy chip 230, and thus, voids remaining between the dummy chip 230 and the uppermost first semiconductor chip 210 may also be removed.

In addition, because the upper surface of the first molding member 390 located inside the channel CH of the dummy chip 230 is exposed upward in the vertical direction Z, it may be easily observed whether the channel CH of the dummy chip 230 is fully filled with the first molding member 390, and voids occurring between the dummy chip 230 and the uppermost first semiconductor chip 210 may also be easily observed.

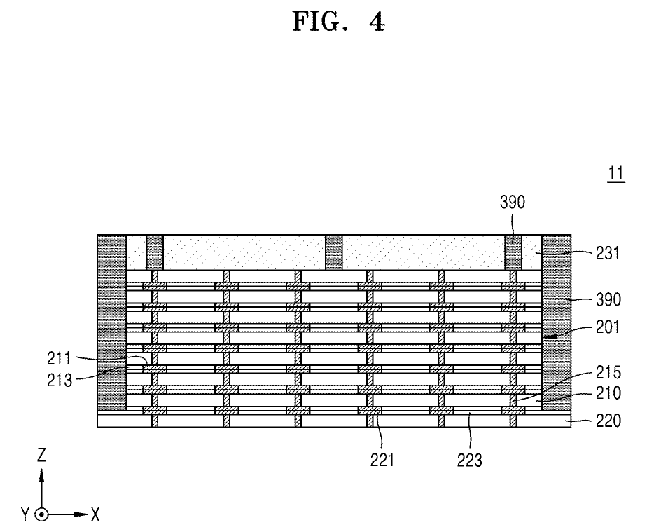

FIG. 3 is a top view schematically illustrating a semiconductor package 11 according to implementations. FIG. 4 is a cross-sectional view taken along line X1-X1' of the semiconductor package 11 of FIG. 3. Hereinafter, the description made with respect to the semiconductor package 10 with reference to FIGS. 1 and 2 is not repeated, and differences between the semiconductor package 10 of FIGS. 1 and 2 and the semiconductor package 11 of FIGS. 3 and 4 are mainly described.

Referring to FIGS. 3 and 4, the semiconductor package 11 may include a chip-stacked structure 201 and the first molding member 390. The chip-stacked structure 201 may include the base chip 220, the first semiconductor chip 210, and a dummy chip 231. The base chip 220 may be the lowermost chip in the chip-stacked structure 201. The first semiconductor chip 210 may be stacked on the base chip 220 in the vertical direction Z. According to implementations, a plurality of first semiconductor chips 210 may be provided. The plurality of first semiconductor chips 210 may be stacked in the vertical direction Z through direct bonding.

According to implementations, the first semiconductor chip 210 may include the semiconductor chip pad 211, the dielectric layer 213, and the first through electrode 215. The semiconductor chip pad 211 may be provided on each of the upper surface and the lower surface of the first semiconductor chip 210. The dielectric layer 213 may surround the semiconductor chip pad 211 on each of the upper surface and the lower surface of the first semiconductor chip 210.

The dummy chip 231 may be stacked on the uppermost first semiconductor chip 210 in the vertical direction Z. According to implementations, the dummy chip 231 may include the channel CH.

The channel CH may have a shape extending in the horizontal direction X and/or Y by passing through the dummy chip 231 from the upper surface to the lower surface of the dummy chip 231 in the vertical direction Z. According to implementations, when the dummy chip 231 is viewed from the top in the vertical direction Z, the channel CH may have a plus (+) shape extending from the center of the dummy chip 231 to at least one point of an edge of the dummy chip 231 in the horizontal direction X and/or Y. For example, as shown in FIG. 3, the channel CH may have a shape extending from the center of the dummy chip 231 to the centers of the four sides in the edge of the dummy chip 231. In addition, the channel CH may further have a rectangular ring shape, wherein a rectangular ring may be formed to connect to the four vertices of the dummy chip 231. Accordingly, the channel CH may act as a passage connecting from the center of the dummy chip 231 to the centers of the four sides of the dummy chip 231 and then the four vertices of the dummy chip 231. According to implementations, the volume of the channel CH in the dummy chip 231 may be within a range of about 1 % to about 3 % of the volume of the dummy chip 231. In some implementations, the cross-section of the channel CH on the X-Z plane may have a rectangular shape.

The dummy chip 231 may be stacked on the upper surface of the uppermost first semiconductor chip 210 through direct bonding. Accordingly, a dielectric layer and a dummy chip pad may be formed on the lower surface of the dummy chip 231.

The first molding member 390 may be formed on the upper surface of the base chip 220 to surround the chip-stacked structure 201. According to implementations, the upper surface of the first molding member 390 may be coplanar with the upper surface of the dummy chip 231. That is, the vertical level of the upper surface of the first molding member 390 may be substantially the same as the vertical level of the upper surface of the dummy chip 231.

The first molding member 390 may fully fill the channel CH of the dummy chip 231. The shape of the first molding member 390 located inside the channel CH of the dummy chip 231 may be substantially the same as the shape of the channel CH. For example, the first molding member 390 located inside the channel CH of the dummy chip 231 may have a shape extending from the center of the dummy chip 231 to at least one point of the edge of the dummy chip 231 when viewing the first molding member 390 from the top in the vertical direction Z. In addition, the cross-section of the first molding member 390 located inside the channel CH of the dummy chip 231, on the X-Z plane, may have a rectangular shape.

The upper surface of the first molding member 390 located inside the channel CH of the dummy chip 231 may be exposed upward from the dummy chip 231 in the vertical direction Z. That is, the upper surface of the first molding member 390 located inside the channel CH of the dummy chip 231 may be coplanar with the upper surface of the dummy chip 231. Because the upper surface of the first molding member 390 located inside the channel CH of the dummy chip 231 is exposed upward in the vertical direction Z, it may be easily observed whether the channel CH of the dummy chip 231 is fully filled with the first molding member 390.

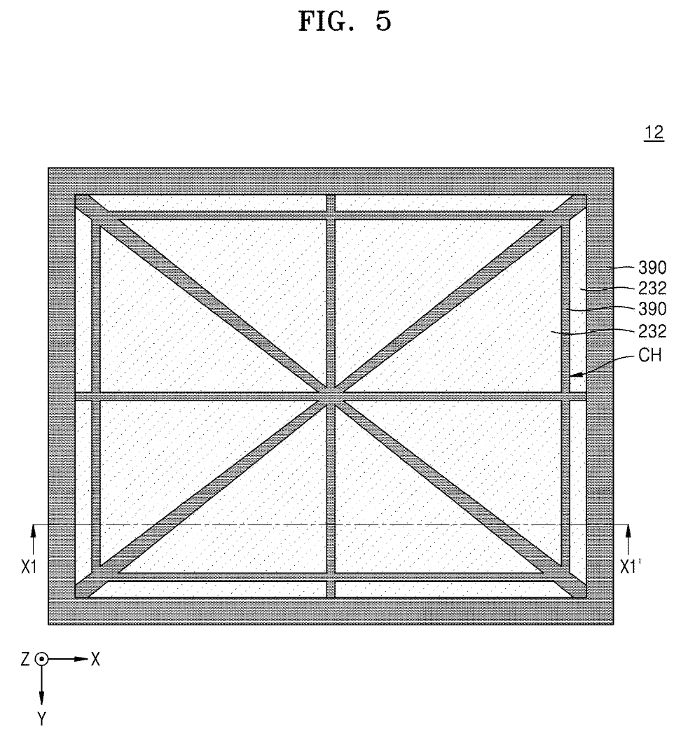

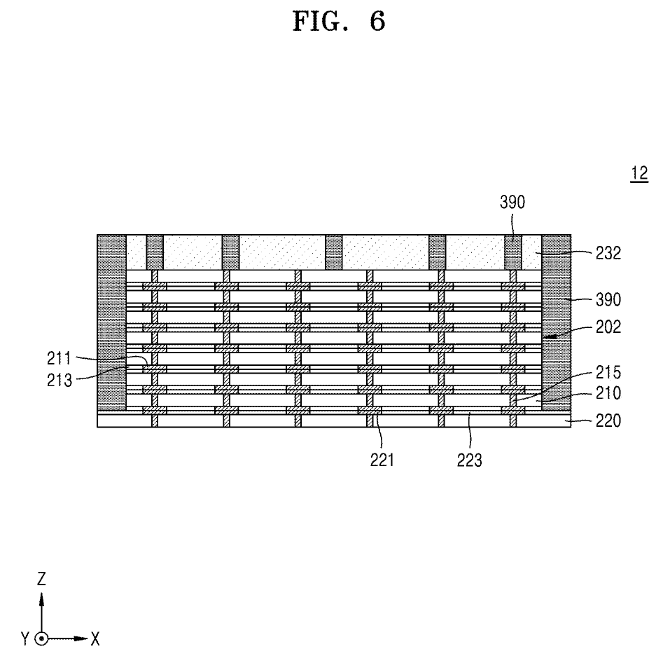

FIG. 5 is a top view schematically illustrating a semiconductor package 12 according to implementations. FIG. 6 is a cross-sectional view taken along line X1-X1' of the semiconductor package 12 of FIG. 5. Hereinafter, the description made with respect to the semiconductor packages 10 and 11 with reference to FIGS. 1 to 4 is not repeated, and differences between the semiconductor packages 10 and 11 of FIGS. 1 to 4 and the semiconductor package 12 of FIGS. 5 and 6 are mainly described.

Referring to FIGS. 5 and 6, the semiconductor package 12 may include a chip-stacked structure 202 and the first molding member 390, and the chip-stacked structure 202 may include the base chip 220, the first semiconductor chip 210, and a dummy chip 232.

The base chip 220 may be the lowermost chip in the chip-stacked structure 202. The first semiconductor chip 210 may be stacked on the base chip 220 in the vertical direction Z. According to implementations, a plurality of first semiconductor chips 210 may be provided. The plurality of first semiconductor chips 210 may be stacked in the vertical direction Z through direct bonding.

According to implementations, the first semiconductor chip 210 may include the semiconductor chip pad 211, the dielectric layer 213, and the first through electrode 215. The semiconductor chip pad 211 may be provided on each of the upper surface and the lower surface of the first semiconductor chip 210. The dielectric layer 213 may surround the semiconductor chip pad 211 on each of the upper surface and the lower surface of the first semiconductor chip 210.

The dummy chip 232 may be stacked on the uppermost first semiconductor chip 210 in the vertical direction Z. According to implementations, the dummy chip 232 may include the channel CH.

The channel CH may have a shape extending in the horizontal direction X and/or Y by passing through the dummy chip 232 from the upper surface to the lower surface of the dummy chip 232 in the vertical direction Z. According to implementations, when the dummy chip 232 is viewed from the top in the vertical direction Z, the channel CH may have a shape extending from the center of the dummy chip 232 to at least one point of an edge of the dummy chip 232 in the horizontal direction X and/or Y. For example, as shown in FIG. 5, the channel CH may have a shape extending from the center of the dummy chip 232 to the centers of the four sides in the edge of the dummy chip 232 and to the four vertices of the dummy chip 232. In addition, the channel CH may further have a rectangular ring shape, wherein a rectangular ring may be formed to connect to the four vertices and the centers of the four sides of the dummy chip 232. Accordingly, the channel CH may have a shape having a combination of a plus shape, an X shape, and a rectangular ring shape when viewing the channel CH from the top in the vertical direction Z.

The channel CH may extend from the center of the dummy chip 232 to the centers of the four sides in the edge of the dummy chip 232 and to the four vertices of the dummy chip 232, and in this case, the channel CH extending from the center of the dummy chip 232 to the centers of the four sides in the edge of the dummy chip 232 and to the four vertices of the dummy chip 232 may be defined by eight lines. The eight lines may be formed by forming substantially 45 degrees therebetween from the center of the dummy chip 232.

According to implementations, the volume of the channel CH in the dummy chip 232 may be within a range of about 1 % to about 3 % of the volume of the dummy chip 232. In some implementations, the cross-section of the channel CH on an X-Z plane may have a rectangular shape.

The dummy chip 232 may be stacked on the upper surface of the uppermost first semiconductor chip 210 through direct bonding. Accordingly, a dielectric layer and a dummy chip pad may be formed on the lower surface of the dummy chip 232.

The first molding member 390 may be formed on the upper surface of the base chip 220 to surround the chip-stacked structure 202. According to implementations, the upper surface of the first molding member 390 may be coplanar with the upper surface of the dummy chip 232. That is, the vertical level of the upper surface of the first molding member 390 may be substantially the same as the vertical level of the upper surface of the dummy chip 232.

The first molding member 390 may fully fill the channel CH of the dummy chip 232. The shape of the first molding member 390 located inside the channel CH of the dummy chip 232 may be substantially the same as the shape of the channel CH. For example, the first molding member 390 located inside the channel CH of the dummy chip 232 may have a shape extending from the center of the dummy chip 232 to at least one point of the edge of the dummy chip 232 when viewing the first molding member 390 from the top in the vertical direction Z. In addition, the cross-section of the first molding member 390 located inside the channel CH of the dummy chip 232, on the X-Z plane, may have a rectangular shape.

The upper surface of the first molding member 390 located inside the channel CH of the dummy chip 232 may be exposed upward from the dummy chip 232 in the vertical direction Z. That is, the upper surface of the first molding member 390 located inside the channel CH of the dummy chip 232 may be coplanar with the upper surface of the dummy chip 232. Because the upper surface of the first molding member 390 located inside the channel CH of the dummy chip 232 is exposed upward in the vertical direction Z, it may be easily observed whether the channel CH of the dummy chip 232 is fully filled with the first molding member 390.

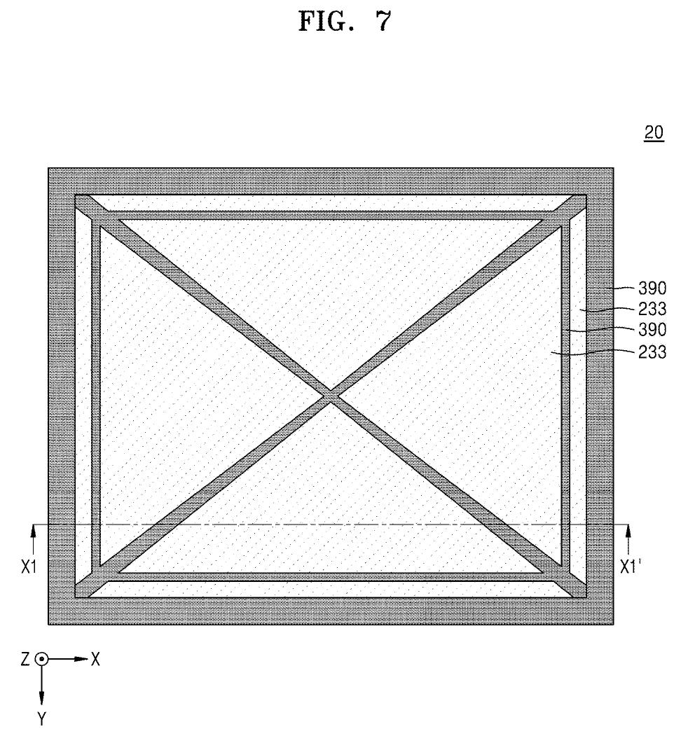

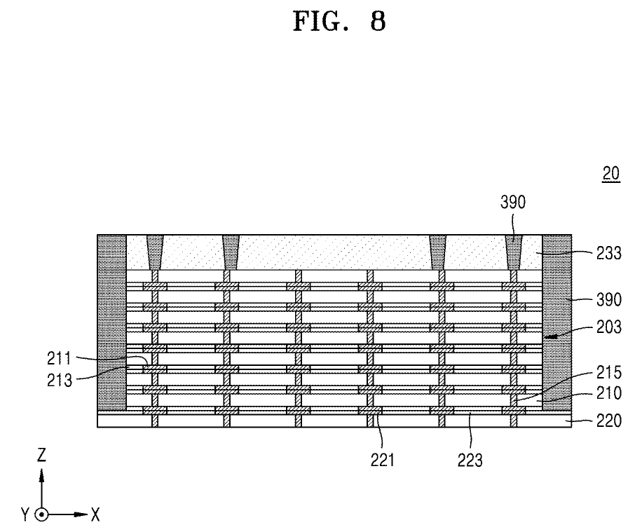

FIG. 7 is a top view schematically illustrating a semiconductor package 20 according to implementations. FIG. 8 is a cross-sectional view taken along line X1-X1' of the semiconductor package 20 of FIG. 7. Hereinafter, the description made with respect to the semiconductor package 10 with reference to FIGS. 1 and 2 is not repeated, and differences between the semiconductor package 10 of FIGS. 1 and 2 and the semiconductor package 20 of FIGS. 7 and 8 are mainly described.

Referring to FIGS. 7 and 8, the semiconductor package 20 may include a chip-stacked structure 203 and a first molding member 390. The chip-stacked structure 203 may include the base chip 220, the first semiconductor chip 210, and a dummy chip 233. The base chip 220 may be the lowermost chip in the chip-stacked structure 203. The first semiconductor chip 210 may be stacked on the base chip 220 in the vertical direction Z. According to implementations, a plurality of first semiconductor chips 210 may be provided. The plurality of first semiconductor chips 210 may be stacked in the vertical direction Z through direct bonding.

According to implementations, the first semiconductor chip 210 may include the semiconductor chip pad 211, the dielectric layer 213, and the first through electrode 215. The semiconductor chip pad 211 may be provided on each of the upper surface and the lower surface of the first semiconductor chip 210. The dielectric layer 213 may surround the semiconductor chip pad 211 on each of the upper surface and the lower surface of the first semiconductor chip 210.

The dummy chip 233 may be stacked on the uppermost first semiconductor chip 210 in the vertical direction Z. According to implementations, the dummy chip 233 may include the channel CH.

The channel CH may have a shape extending in the horizontal direction X and/or Y by passing through the dummy chip 233 from the upper surface to the lower surface of the dummy chip 233 in the vertical direction Z. According to implementations, when the dummy chip 233 is viewed from the top in the vertical direction Z, the channel CH may have a shape extending from the center of the dummy chip 233 to at least one point of an edge of the dummy chip 233 in the horizontal direction X and/or Y.

According to implementations, the cross-section of the channel CH on the X-Z plane may have a tapered shape of which the horizontal width gradually decreases as the vertical level thereof decreases. For example, the channel CH may have a shape of which the horizontal width gradually decreases toward the uppermost first semiconductor chip 210. However, the cross-section of the channel CH on the X-Z plane is not limited thereto and may have a shape of which the horizontal width gradually increases as the vertical level thereof decreases and have various shapes other than a trapezoidal shape.

The dummy chip 233 may be stacked on the upper surface of the uppermost first semiconductor chip 210 through direct bonding. Accordingly, a dielectric layer and a dummy chip pad may be formed on the lower surface of the dummy chip 233.

The first molding member 390 may be formed on the upper surface of the base chip 220 to surround the chip-stacked structure 203. According to implementations, the upper surface of the first molding member 390 may be coplanar with the upper surface of the dummy chip 233. That is, the vertical level of the upper surface of the first molding member 390 may be substantially the same as the vertical level of the upper surface of the dummy chip 233.

The first molding member 390 may fully fill the channel CH of the dummy chip 233. The shape of the first molding member 390 located inside the channel CH of the dummy chip 233 may be substantially the same as the shape of the channel CH. For example, the first molding member 390 located inside the channel CH of the dummy chip 233 may have a shape extending from the center of the dummy chip 233 to at least one point of the edge of the dummy chip 233 when viewing the first molding member 390 from the top in the vertical direction Z. In addition, the cross-section of the first molding member 390 located inside the channel CH of the dummy chip 233, on the X-Z plane, may have a tapered shape of which the horizontal width gradually decreases as the vertical level of the first molding member 390 decreases.

Because the semiconductor package 20 according to the technical idea of the present disclosure has the channel CH of which the horizontal width gradually decreases as the vertical level thereof decreases, the horizontal width of the channel CH may be maximized at the upper surface of the dummy chip 233. Accordingly, when the dummy chip 233 is bonded onto the uppermost first semiconductor chip 210, gas remaining inside voids may be easily discharged along the channel CH, thereby reducing voids between the dummy chip 233 and the uppermost first semiconductor chip 210.

In addition, because the horizontal width of the channel CH is maximized at the upper surface of the dummy chip 233, the first molding member 390 filling the channel CH may easily fill the channel CH according to an effect that the entrance of the channel CH increases.

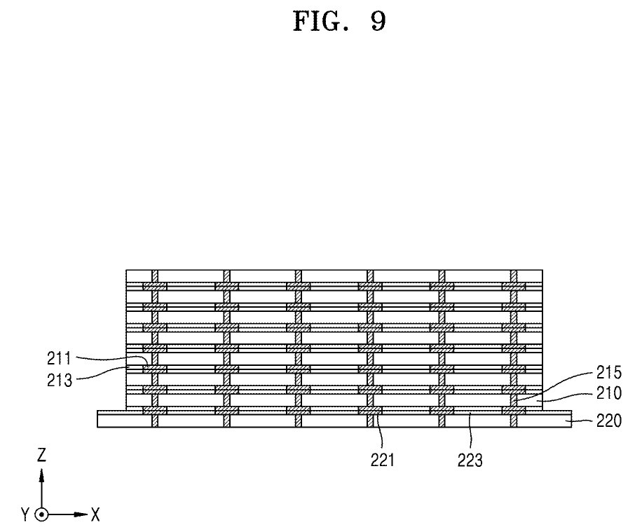

FIGS. 9 to 12B are cross-sectional views for describing methods of manufacturing semiconductor packages, according to implementations. Hereinafter, the description made with reference to FIGS. 1 to 8 is omitted, and differences from the description are mainly described.

First, referring to FIG. 9. the plurality of first semiconductor chips 210 are bonded onto the base chip 220. The plurality of first semiconductor chips 210 may be connected onto the base chip 220 through direct bonding.

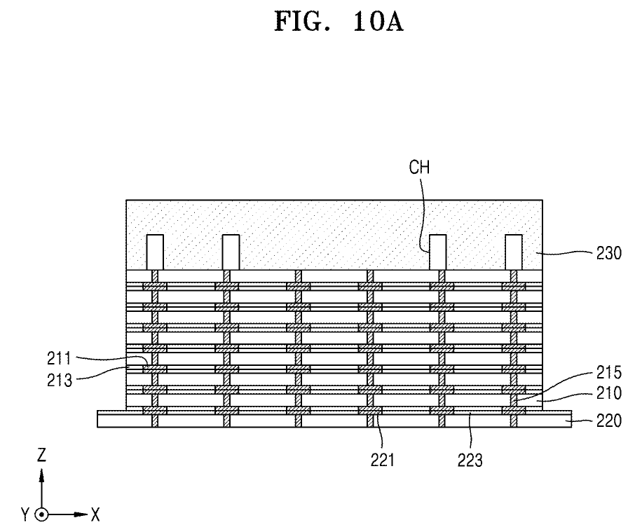

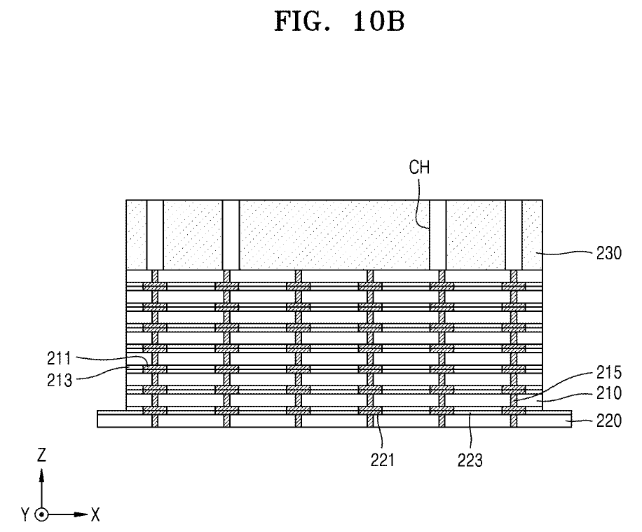

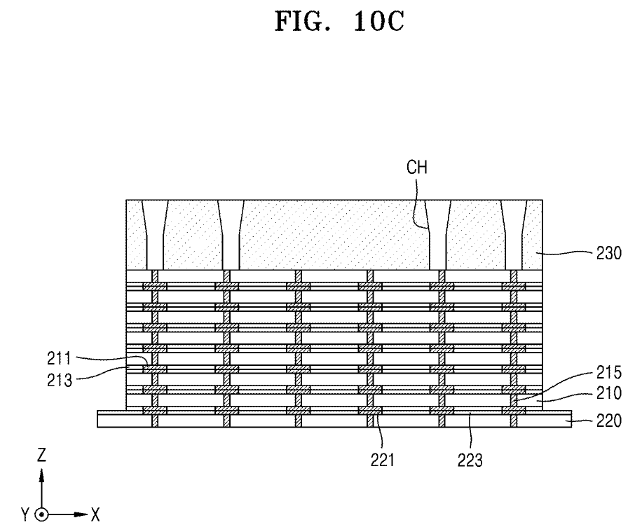

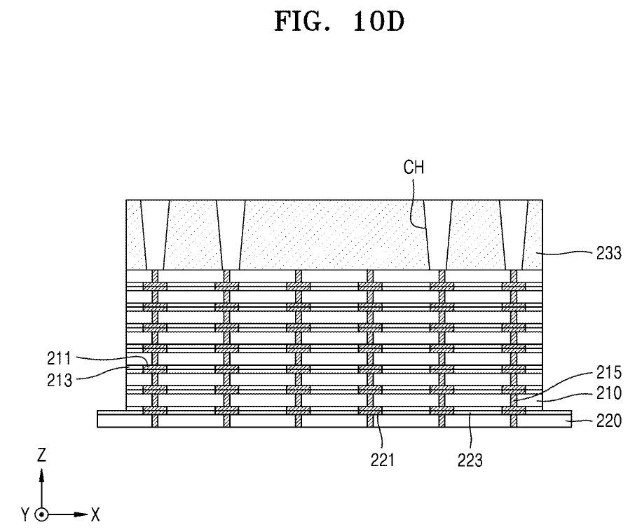

Referring to FIGS. 10A to 10C, the dummy chip 230 having the channel CH formed therein is stacked on the uppermost first semiconductor chip 210 in FIG. 9. In addition, referring to FIG. 10D, the dummy chip 233 having the channel CH formed therein is stacked on the uppermost first semiconductor chip 210 in FIG. 9.

In this case, the dummy chip 230 or 233 may be stacked on the uppermost first semiconductor chip 210 through direct bonding. The dummy chip 230 or 233 may not be electrically connected to (e.g., be insulated from) the uppermost first semiconductor chip 210.

In some implementations, as shown in FIG. 10A, the channel CH of the dummy chip 230 may extend from the lower surface of the dummy chip 230 to a certain height without extending to the upper surface of the dummy chip 230.

In some implementations, as shown in FIG. 10B, the channel CH of the dummy chip 230 may extend from the lower surface of the dummy chip 230 to the upper surface of the dummy chip 230. In addition, the cross-section of the channel CH on the X-Z plane may have a rectangular shape. The side surface of the cross-section of the channel CH on the X-Z plane may be perpendicular to the upper surface of the uppermost first semiconductor chip 210.

In some implementations, as shown in FIG. 10C, the channel CH of the dummy chip 230 may extend from the lower surface of the dummy chip 230 to the upper surface of the dummy chip 230, and the cross-section of the channel CH on the X-Z plane may have a horizontal width that is constant from the lower surface of the dummy chip 230 to a certain height and gradually increases from the certain height to the upper surface of the dummy chip 230 as the vertical level of the dummy chip 230 increases. Herein, the certain height may indicate a height between the lower and upper surfaces of the dummy chip 230.

In some implementations, as shown in FIG. 10D, the channel CH of the dummy chip 233 may extend from the lower surface of the dummy chip 230 to the upper surface of the dummy chip 233, and the cross-section of the channel CH on the X-Z plane may have a trapezoidal shape. The trapezoidal shape may have a shape of which the horizontal width gradually increases as the vertical level of the trapezoidal shape increases.

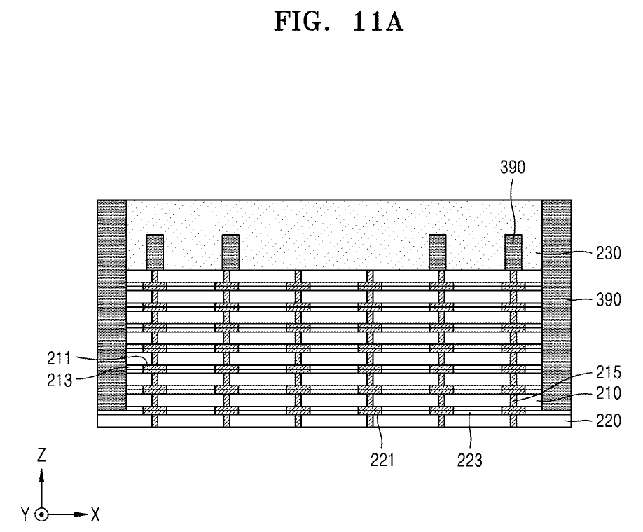

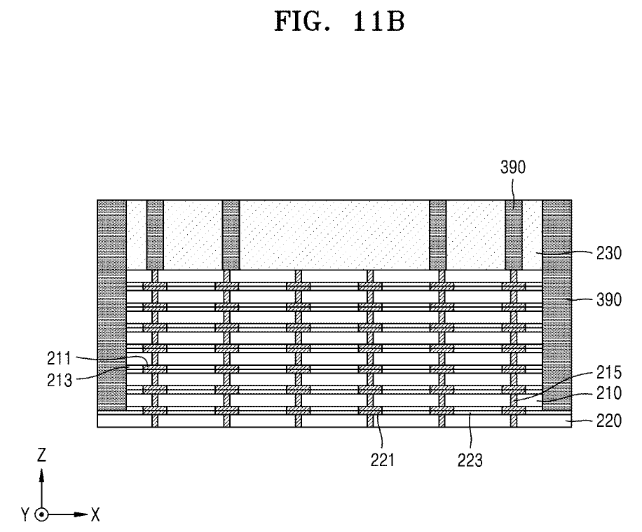

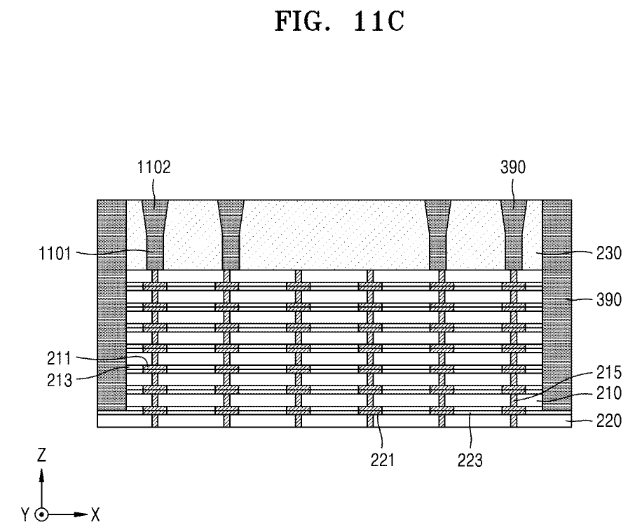

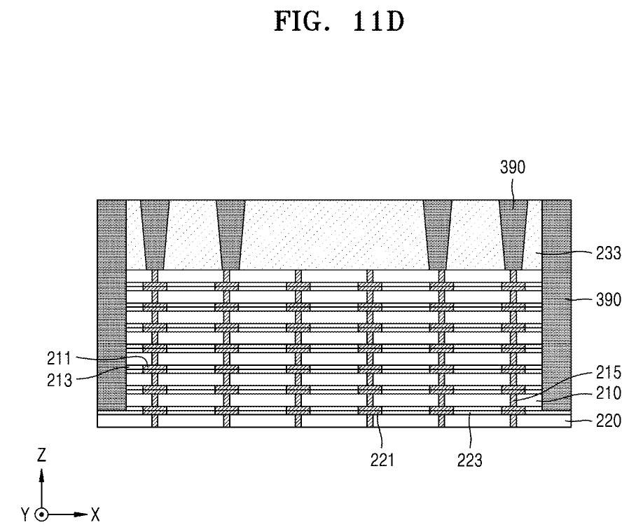

Referring to FIGS. 11A to 11D, it may be understood that FIG. 11A shows the first molding member 390 formed with reference to FIG. 10A, FIG. 11B shows the first molding member 390 formed with reference to FIG. 10B, FIG. 11C shows the first molding member 390 formed with reference to FIG. 10C, and FIG. 11D shows the first molding member 390 formed with reference to FIG. 10D.

Referring to FIG. 11A, the first molding member 390 may be formed on the base chip 220 to cover the plurality of first semiconductor chips 210 and the dummy chip 230. The first molding member 390 may fill the channel CH of the dummy chip 230. In this case, the first molding member 390 may flow into the channel CH inside the dummy chip 230 along the entrance of the channel CH, which is formed in the surface of the dummy chip 230. In FIG. 11A, the first molding member 390 may flow into the channel CH inside the dummy chip 230 through the entrance of the channel CH, which is formed in the side surface of the dummy chip 230.

Referring to FIG. 11B, the first molding member 390 may be formed on the base chip 220 to cover the plurality of first semiconductor chips 210 and the dummy chip 230. The first molding member 390 may fill the channel CH of the dummy chip 230. In this case, the first molding member 390 may flow into the channel CH inside the dummy chip 230 along the entrance of the channel CH, which is formed in the surface of the dummy chip 230. In FIG. 11B, the first molding member 390 may flow into the channel CH inside the dummy chip 230 through the entrance of the channel CH, which is formed in the side surface of the dummy chip 230, and the entrance of the channel CH, which is formed in the upper surface of the dummy chip 230. In FIG. 11B, because the channel CH extends from the lower surface of the dummy chip 230 to the upper surface of the dummy chip 230, the first molding member 390 may flow into the channel CH of the dummy chip 230 through not only the side surface of the dummy chip 230 but also the upper surface of the dummy chip 230. By doing this, the first molding member 390 may easily fill the channel CH of the dummy chip 230.

Referring to FIG. 11C, the first molding member 390 may be formed on the base chip 220 to cover the plurality of first semiconductor chips 210 and the dummy chip 230. The first molding member 390 may fill the channel CH of the dummy chip 230. In this case, the first molding member 390 may flow into the channel CH inside the dummy chip 230 along the entrance of the channel CH, which is formed in the surface of the dummy chip 230. In FIG. 11C, the first molding member 390 may flow into the channel CH inside the dummy chip 230 through the entrance of the channel CH, which is formed in the side surface of the dummy chip 230, and the entrance of the channel CH, which is formed in the upper surface of the dummy chip 230. In addition, in FIG. 11C, the channel CH may extend from the lower surface of the dummy chip 230 to the upper surface of the dummy chip 230, and because the channel CH has a shape of which the horizontal width gradually increases as the vertical level of the channel CH increases at a certain vertical level and higher, the horizontal width of the channel CH may be maximized at the upper surface of the dummy chip 230. Accordingly, the first molding member 390 flowing into the channel CH through the upper surface of the dummy chip 230 may easily fill the channel CH. For example, as shown in FIG. 11C, the channel CH can include a first part 1101 and a second part 1102 on the first part 1101 along Z direction. The first part 1101 is between the second part 1102 and the uppermost first semiconductor chip. The first part 1101 can have a constant width, while the second part 1102 can have a width that gradually decreases from the upper surface of the dummy chip 230 to the first part 1101.

Referring to FIG. 11D, the first molding member 390 may be formed on the base chip 220 to cover the plurality of first semiconductor chips 210 and the dummy chip 233. The first molding member 390 may fill the channel CH of the dummy chip 233. In this case, the first molding member 390 may flow into the channel CH inside the dummy chip 233 along the entrance of the channel CH, which is formed in the surface of the dummy chip 233. In FIG. 11D, the first molding member 390 may flow into the channel CH inside the dummy chip 233 through the entrance of the channel CH, which is formed in the side surface of the dummy chip 233, and the entrance of the channel CH, which is formed in the upper surface of the dummy chip 233. In FIG. 11D, the channel CH may extend from the lower surface of the dummy chip 233 to the upper surface of the dummy chip 233, and because the channel CH has a shape of which the horizontal width gradually increases as the vertical level of the channel CH increases, the first molding member 390 flowing into the channel CH through the upper surface of the dummy chip 233 may easily fill the channel CH.

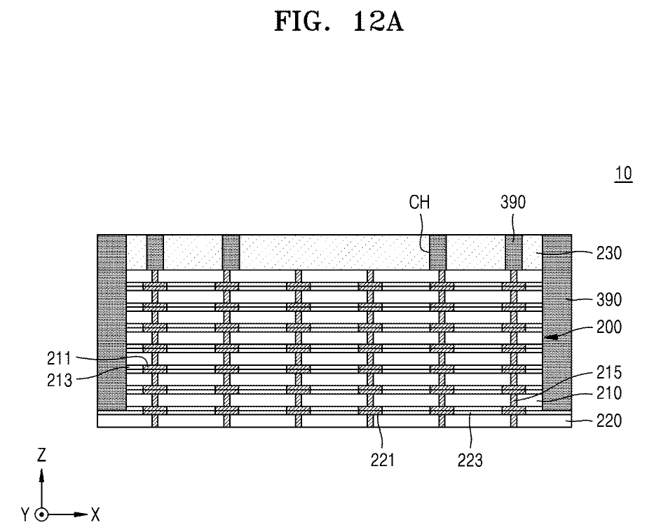

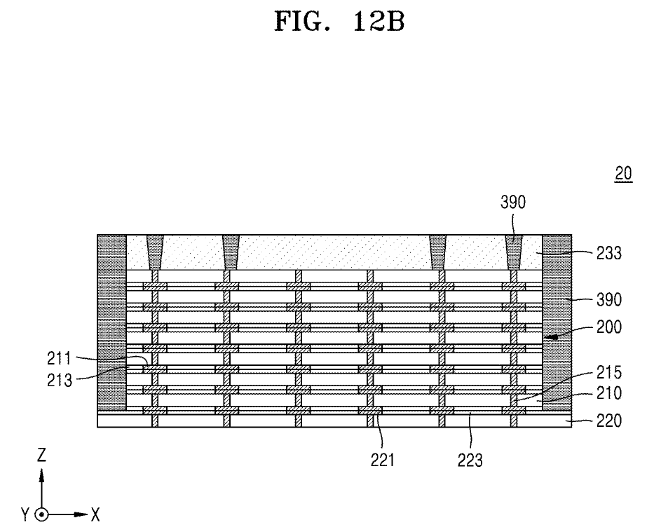

Referring to FIGS. 12A and 12B, the semiconductor package 10 or 20 is provided by etching the dummy chip 230 or 233 to a certain height with reference to FIGS. 11A to 11D through a chemical mechanical polishing (CMP) process or the like. In this case, the first molding member 390 filling the channel CH of the dummy chip 230 or 233 may be exposed through the upper surface of the dummy chip 230 or 233.

In this case, FIG. 12A shows that the dummy chip 230 is etched with reference to FIGS. 11A to 11C, and FIG. 12B shows that the dummy chip 233 is etched with reference to FIG. 11D.

FIG. 13 is a cross-sectional view schematically illustrating a semiconductor package 30 according to implementations. Hereinafter, the description made with respect to the semiconductor package 10 with reference to FIGS. 1 and 2 is not repeated, and differences between the semiconductor package 10 of FIGS. 1 and 2 and the semiconductor package 30 of FIG. 13 are mainly described.

Referring to FIG. 13, the semiconductor package 30 may include the first substrate 100, the semiconductor package 10 including a chip-stacked structure, the first molding member 390, and a second molding member 490. The first substrate 100 may be a substrate on which the semiconductor package 10 including the chip-stacked structure is mounted, and may be located under the semiconductor package 10 including the chip-stacked structure. Particularly, the first substrate 100 may be located between the semiconductor package 10 including the chip-stacked structure and an external connection terminal 160. The first substrate 100 may be electrically connected to each of the semiconductor package 10 including the chip-stacked structure and the external connection terminal 160. According to implementations, the first substrate 100 may have a shape in which at least one of the upper and lower surfaces of the first substrate 100 is flat. According to implementations, a plurality of semiconductor packages may be mounted on the first substrate 100, and the plurality of semiconductor packages may be various types of semiconductor packages.

The first substrate 100 may include an insulating layer and a wiring formed in the insulating layer. According to implementations, the first substrate 100 may include a redistribution structure formed through a redistribution process. In this case, the wiring of the first substrate 100 may be understood as a redistribution pattern, and the insulating layer of the first substrate 100 may be understood as a redistribution insulating layer. Herein, the wiring of the first substrate 100 may include a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy of the metal but is not limited thereto, and in some implementations, the wiring may be formed by stacking a metal or an alloy of the metal on a seed layer including Cu, Ti, titanium nitride, or titanium tungsten. In addition, the insulating layer of the first substrate 100 may be formed of photo imageable dielectric (PID) or photosensitive polyimide (PSPI).

However, the first substrate 100 is not limited thereto, and in some implementations, the first substrate 100 may be formed based on a ceramic substrate, a printed circuit board (PCB), an organic substrate, or the like. In this case, the wiring of the first substrate 100 may include Cu, Ni, stainless steel, or beryllium copper, and the insulating layer of the first substrate 100 may include at least one material selected from among FR-4, tetrafunctional epoxy, polyphenylene ether, epoxy/polyphenylene oxide, BT, Thermount, cyanate ester, polyimide, and liquid crystal polymer.

The external connection terminal 160 may be disposed on the lower surface of the first substrate 100 and electrically connected to the first substrate 100 via a pad formed on the lower surface of the first substrate 100. Particularly, the external connection terminal 160 may be electrically connected to wirings, formed in the first substrate 100, via a substrate pad attached to the lower surface of the first substrate 100. Because the external connection terminal 160 is beneath the first substrate 100, the upper surface of the external connection terminal 160 may be in physical contact with the substrate pad attached to the lower surface of the first substrate 100. The external connection terminal 160 may be electrically connected to an external device, for example, a motherboard, a PCB, a package substrate, or the like. Because the external connection terminal 160 is provided between the external device and the first substrate 100, the lower surface of the external connection terminal 160 may be physically connected to the external device.

The external connection terminal 160 may be formed as a solder ball. However, according to an implementation, the external connection terminal 160 may have a structure including a pillar and solder. The external connection terminal 160 may include at least one of Cu, silver (Ag), gold (Au), and Sn.

According to implementations, the semiconductor package 10 including the chip-stacked structure may be mounted on the upper surface of the first substrate 100 through a first bump 190. The first bump 190 may be provided between the semiconductor package 10 including the chip-stacked structure and the first substrate 100. The first bump 190 may include a pillar structure, a ball structure, or a solder layer.

According to implementations, an under-fill material layer 150 surrounding the first bump 190 may be provided between the semiconductor package 10 including the chip-stacked structure and the first substrate 100. The under-fill material layer 150 may include an epoxy resin formed by, for example, a capillary under-fill process. However, in some implementations, the second molding member 490 may directly fill the gap between the semiconductor package 10 including the chip-stacked structure and the first substrate 100 by a molded under-fill process. In this case, the under-fill material layer 150 may be omitted.

The semiconductor package 10 including the chip-stacked structure may include the base chip 220, the plurality of first semiconductor chips 210, and the dummy chip 230. According to implementations, the first semiconductor chip 210 may include the semiconductor chip pad 211, the dielectric layer 213, and the first through electrode 215. The plurality of first semiconductor chips 210 may be stacked on the base chip 220 in the vertical direction Z through direct bonding.

The dummy chip 230 may be stacked on the uppermost first semiconductor chip 210 in the vertical direction Z. According to implementations, the dummy chip 230 may include the channel CH.

The channel CH may have a shape extending in the horizontal direction X and/or Y by passing through the dummy chip 230 from the upper surface to the lower surface of the dummy chip 230 in the vertical direction Z. According to implementations, when the dummy chip 230 is viewed from the top in the vertical direction Z, the channel CH may have a shape extending from the center of the dummy chip 230 to at least one point of the edge of the dummy chip 230 in the horizontal direction X and/or Y. The shape of the channel CH may be substantially the same as any of those of the implementations described with reference to FIGS. 1 to 8, and thus, a detailed description thereof is omitted herein.

The first molding member 390 may be formed on the upper surface of the base chip 220 to surround the plurality of first semiconductor chips 210 and the dummy chip 230. The first molding member 390 may fully fill the channel CH formed in the dummy chip 230.

The second molding member 490 may surround the side surface of the base chip 220 and the side surface of the first molding member 390 on the first substrate 100. In some implementations, the second molding member 490 may include the same material as the first molding member 390. However, in some implementations, the second molding member 490 may include a material different from that of the first molding member 390. According to implementations, the upper surface of the second molding member 490 may be coplanar with the upper surface of the first molding member 390.

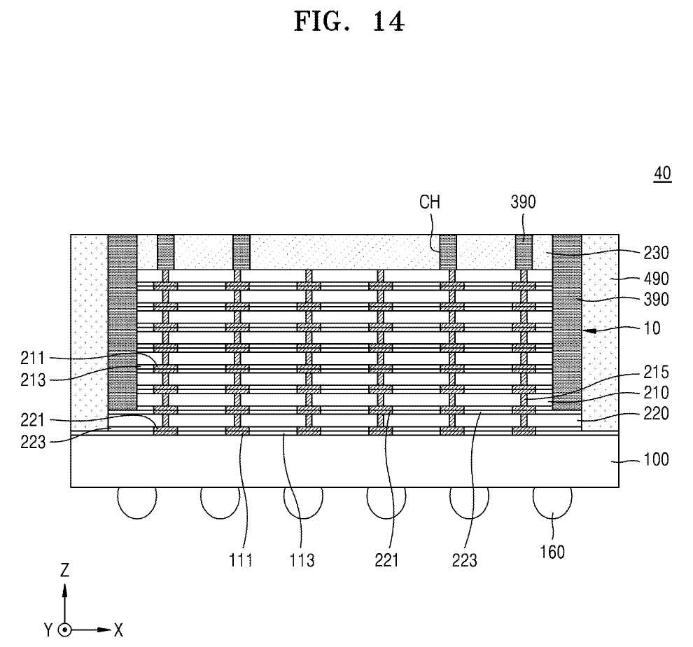

FIG. 14 is a cross-sectional view schematically illustrating a semiconductor package 40 according to implementations. Hereinafter, the description made with respect to the semiconductor package 30 with reference to FIG. 13 is not repeated, and differences between the semiconductor package 30 of FIG. 13 and the semiconductor package 40 of FIG. 14 are mainly described.

Referring to FIG. 14, the semiconductor package 40 may include the first substrate 100, the semiconductor package 10 including a chip-stacked structure, the first molding member 390, and the second molding member 490. The first substrate 100 is a substrate on which the semiconductor package 10 including the chip-stacked structure is mounted, and may be located under the semiconductor package 10 including the chip-stacked structure. The external connection terminal 160 may be on the lower surface of the first substrate 100 and electrically connected to the first substrate 100 via a pad formed on the lower surface of the first substrate 100.

According to implementations, the semiconductor package 10 including the chip-stacked structure may be mounted on the first substrate 100 through direct bonding. Particularly, the semiconductor package 10 including the chip-stacked structure may be directly bonded to a first substrate pad 111 and a dielectric layer 113 surrounding the first substrate pad 111 through the base chip pad 221 formed on the lower surface of the base chip 220 and the dielectric layer 223 surrounding the base chip pad 221. Accordingly, a solder bump or the like may not be provided between the semiconductor package 10 including the chip-stacked structure and the first substrate 100.

The dummy chip 230 may be stacked on the uppermost first semiconductor chip 210 in the vertical direction Z. According to implementations, the dummy chip 230 may include the channel CH.

The channel CH may have a shape extending in the horizontal direction X and/or Y by passing through the dummy chip 230 from the upper surface to the lower surface of the dummy chip 230 in the vertical direction Z. According to implementations, when the dummy chip 230 is viewed from the top in the vertical direction Z, the channel CH may have a shape extending from the center of the dummy chip 230 to at least one point of the edge of the dummy chip 230 in the horizontal direction X and/or Y. The shape of the channel CH may be substantially the same as any of those of the implementations described with reference to FIGS. 1 to 8, and thus, a detailed description thereof is omitted herein.

The first molding member 390 may surround the plurality of first semiconductor chips 210 and the dummy chip 230 on the upper surface of the base chip 220. The first molding member 390 may fully fill the channel CH formed in the dummy chip 230.

The second molding member 490 may surround the side surface of the base chip 220 and the side surface of the first molding member 390 on the first substrate 100. In some implementations, the second molding member 490 may include the same material as the first molding member 390. However, in some implementations, the second molding member 490 may include a material different from that of the first molding member 390. According to implementations, the upper surface of the second molding member 490 may be coplanar with the upper surface of the first molding member 390.

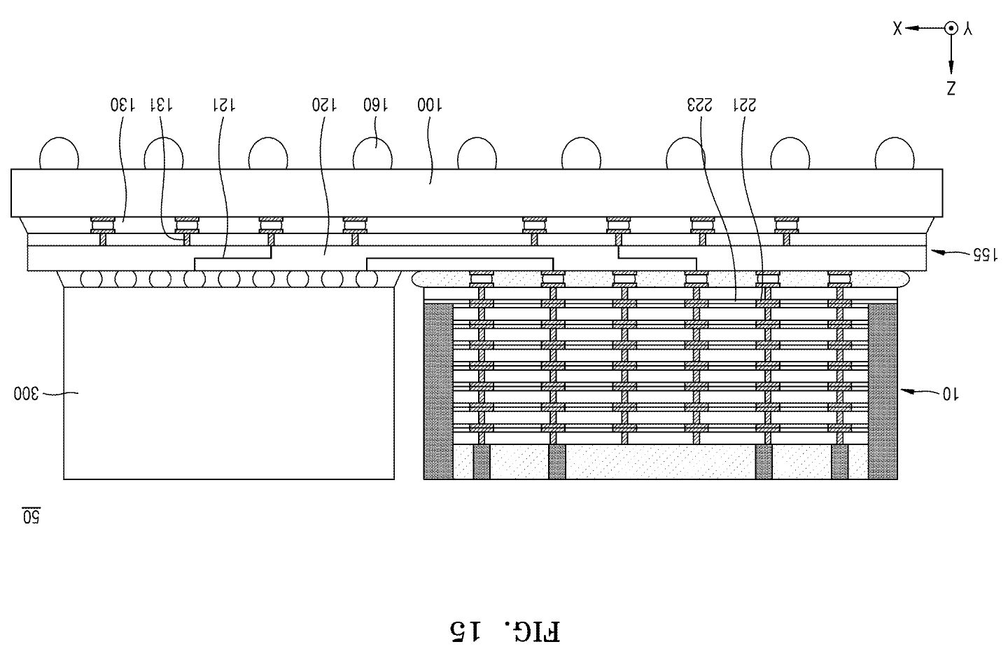

FIG. 15 is a cross-sectional view schematically illustrating a semiconductor package 50 according to implementations. Hereinafter, the description made with reference to FIGS. 1 to 14 is omitted, and differences from the description are mainly described.

Referring to FIGS. 1 and 15, the semiconductor package 50 may include the first substrate 100, an interposer 155, the semiconductor package 10 including a chip-stacked structure, and a second semiconductor chip 300. The first substrate 100 may be a substrate on which the semiconductor package 10 including the chip-stacked structure and the second semiconductor chip 300 are mounted. The external connection terminal 160 may be disposed on the lower surface of the first substrate 100 and electrically connected to the first substrate 100 via a pad formed on the lower surface of the first substrate 100.

The interposer 155 may include an interposer substrate 130, a wiring layer 120, and a through electrode 131. The interposer 155 may be disposed such that the interposer substrate 130 faces the first substrate 100. According to implementations, the interposer substrate 130 may be formed based on Si. The through electrode 131 may pass through the interposer substrate 130 in the vertical direction Z. The through electrode 131 may be electrically connected to the first substrate 100 via a pad and a bump formed on the lower surface of the interposer substrate 130. The wiring layer 120 may include a wiring pattern 121. The wiring pattern 121 may electrically connect the semiconductor package 10 including the chip-stacked structure and the second semiconductor chip 300 to each other or electrically connect between the semiconductor package 10 including the chip-stacked structure and the through electrode 131 and between the second semiconductor chip 300 and the through electrode 131.

The semiconductor package 10 including the chip-stacked structure may include the base chip 220, the plurality of first semiconductor chips 210, and the dummy chip 230. According to implementations, the first semiconductor chip 210 may include the semiconductor chip pad 211, the dielectric layer 213, and the first through electrode 215. The plurality of first semiconductor chips 210 may be stacked on the base chip 220 in the vertical direction Z through direct bonding. The semiconductor package 10 including the chip-stacked structure may be mounted on the interposer 155 through flip-chip or direct bonding.

The dummy chip 230 may be stacked on the uppermost first semiconductor chip 210 in the vertical direction Z. According to implementations, the dummy chip 230 may include the channel CH.

The channel CH may have a shape extending in the horizontal direction X and/or Y by passing through the dummy chip 230 from the upper surface to the lower surface of the dummy chip 230 in the vertical direction Z. According to implementations, when the dummy chip 230 is viewed from the top in the vertical direction Z, the channel CH may have a shape extending from the center of the dummy chip 230 to at least one point of the edge of the dummy chip 230 in the horizontal direction X and/or Y. The shape of the channel CH may be substantially the same as any of those of the implementations described with reference to FIGS. 1 to 8, and thus, a detailed description thereof is omitted herein.

The first molding member 390 may be formed on the upper surface of the base chip 220 to surround the semiconductor package 10 including the chip-stacked structure. That is, the first molding member 390 may surround the plurality of first semiconductor chips 210 and the dummy chip 230 on the upper surface of the base chip 220. The first molding member 390 may fully fill the channel CH formed in the dummy chip 230.

The second semiconductor chip 300 may be mounted on the interposer 155. The second semiconductor chip 300 may include a logic chip. The logic chip may be a microprocessor, such as a CPU, a GPU, or an AP, an analog device, or a digital signal processor.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor package comprising:
a base chip;
a plurality of first semiconductor chips on the base chip;
a dummy chip on an uppermost first semiconductor chip of the plurality of first semiconductor chips; and
a molding structure surrounding the base chip, the plurality of first semiconductor chips, and the dummy chip,
wherein the dummy chip comprises a channel extending from an upper surface of the dummy chip to a lower surface of the dummy chip along a first direction, the channel extending from a center of the dummy chip to an edge of the dummy chip along a second direction perpendicular to the first direction, and
wherein the molding structure is disposed at the channel.

2. The semiconductor package of claim 1, wherein the channel comprises:
a first portion having an X shape in a plane perpendicular to the first direction, the first portion extending from the center of the dummy chip to four vertices of the dummy chip; and
a second portion having a rectangular ring shape in the plane, the second portion partially overlapping the first portion.

3. The semiconductor package of claim 1, wherein the channel comprises:
a first portion having a plus sign shape in a plane perpendicular to the first direction, the first portion extending from the center of the dummy chip to centers of four sides of the dummy chip; and
a second portion having a rectangular ring shape in the plane, the second portion partially overlapping the first portion.

4. The semiconductor package of claim 1, wherein the channel comprises:
a first portion having an X shape in a plane perpendicular to the first direction, the first portion extending from the center of the dummy chip to four vertices of the dummy chip;
a second portion having a plus sign shape in the plane, the second portion extending from the center of the dummy chip to centers of four sides of the dummy chip; and
a third portion having a rectangular ring shape in the plane.

5. The semiconductor package of claim 1, wherein the channel comprises a first part and a second part stacked along the first direction, and
wherein a width of the first part of the channel along the second direction is different from a width of the second part of the channel along the second direction.

6. The semiconductor package of claim 5, wherein a cross-section of the channel in a plane that is parallel to the first direction has a trapezoidal shape, and
wherein the width of the channel along the second direction gradually decreases towards the uppermost first semiconductor chip.

7. The semiconductor package of claim 1, wherein a volume of the molding structure disposed at the channel is within a range of about 1 % to about 3 % of a total volume of the dummy chip.

8. The semiconductor package of claim 1, wherein an upper surface of the molding structure disposed at the channel is coplanar with the upper surface of the dummy chip.

9. The semiconductor package of claim 1, wherein the dummy chip is insulated from the uppermost first semiconductor chip.

10. The semiconductor package of claim 1, wherein the plurality of first semiconductor chips is free of a bump between adjacent first semiconductor chips of the plurality of first semiconductor chips.

11. A semiconductor package comprising:
a base chip;
a plurality of first semiconductor chips on the base chip along a first direction; and
a dummy chip on an uppermost first semiconductor chip of the plurality of first semiconductor chips, the dummy chip having a channel extending upward from a lower surface of the dummy chip,
wherein the channel extends from a center of the dummy chip to at least four points located at an edge of the dummy chip,
wherein the plurality of first semiconductor chips are stacked through direct bonding, and
wherein the dummy chip is insulated from the uppermost first semiconductor chip.

12. The semiconductor package of claim 11, wherein the channel extends from a lower surface of the dummy chip to an upper surface of the dummy chip along the first direction,
wherein the channel comprises a first part and a second part arranged on the first part along the first direction, the first part being between the second part and the uppermost first semiconductor chip along the first direction, and
wherein a width of the first part along a second direction perpendicular to the first direction is constant, and a width of the second part along the second direction gradually increases towards the upper surface of the dummy chip.

13. The semiconductor package of claim 11, wherein the channel extends from a lower surface of the dummy chip to an upper surface of the dummy chip along the first direction,
wherein a cross-section of the channel in a plane parallel to the first direction has a trapezoidal shape, and
wherein a width of the channel along a second direction gradually decreases from the upper surface of the dummy chip towards the lower surface of the dummy chip, the second direction being perpendicular to the first direction.

14. The semiconductor package of claim 11, wherein the channel comprises:
a first portion having an X shape in a plane perpendicular to the first direction, the first portion extending from the center of the dummy chip to four vertices of the dummy chip; and
a second portion having a rectangular ring shape in the plane, the second portion partially overlapping the first portion.

15. The semiconductor package of claim 11, wherein the channel comprises:
a first portion having a plus sign shape in a plane perpendicular to the first direction, the first portion extending from the center of the dummy chip to centers of four sides of the dummy chip; and
a second portion having a rectangular ring shape in the plane, the second portion partially overlapping the first portion.

16. The semiconductor package of claim 11, wherein the channel comprises:
a first portion having an X shape in a plane perpendicular to the first direction, the first portion extending from the center of the dummy chip to four vertices of the dummy chip; and
a second portion having a plus sign shape in the plane, the second portion extending from the center of the dummy chip to centers of four sides of the dummy chip; and
a third portion having a rectangular ring shape in the plane.

17. A semiconductor package comprising:
a first substrate;
a base chip on the first substrate along a first direction;
a plurality of first semiconductor chips stacked on the base chip along the first direction;
a dummy chip on an uppermost first semiconductor chip of the plurality of first semiconductor chips, the dummy chip having a channel extending from a lower surface of the dummy chip to an upper surface of the dummy chip along the first direction;
a first molding structure surrounding the base chip, the plurality of first semiconductor chips, and the dummy chip, the first molding structure filling the channel; and
a second molding structure surrounding side surfaces of the first molding structure and the base chip on the first substrate
wherein a semiconductor chip pad and a dielectric layer surrounding a side surface of the semiconductor chip pad are on each of lower surfaces and upper surfaces of the plurality of first semiconductor chips,
wherein the channel extends from a center of the dummy chip to at least four points located at an edge of the dummy chip in a first plane perpendicular to the first direction, and
wherein an upper surface of the first molding structure is coplanar with the upper surface of the dummy chip.

18. The semiconductor package of claim 17, wherein a cross-section of the channel in a second plane parallel to the first direction has a trapezoidal shape, and a width of the channel along a second direction gradually decreases towards the uppermost first semiconductor chip, the second direction being perpendicular to the first direction.

19. The semiconductor package of claim 17, wherein the channel comprises:
a first portion having an X shape in the first plane, the first portion extending from the center of the dummy chip to four vertices of the dummy chip;
a second portion having a plus sign shape in the first plane, the second portion extending from the center of the dummy chip to centers of four sides of the dummy chip; and
a third portion having a rectangular ring shape in the first plane.

20. The semiconductor package of claim 17, comprising:
an interposer between the first substrate and the base chip; and
a second semiconductor chip on the interposer, the second semiconductor chip being spaced apart from the base chip along a second direction perpendicular to the first direction.
